(19) United States
(12) Patent Application Publication
(10) Pub. No.: US 2023/0163565 A1
(43) Pub. Date: May 25, 2023

(54) SEMICONDUCTOR LASER DEVICE, METHOD FOR MANUFACTURING A SEMICONDUCTOR LASER DEVICE AND PROJECTION DEVICE

(71) Applicant: OSRAM Opto Semiconductors GmbH, Regensburg (DE)

(72) Inventors: Hubert HALBRITTER, Dietfurt (DE); Ann RUSSELL, San Jose, CA (US)

(21) Appl. No.: 17/530,903

(22) Filed: Nov. 19, 2021

(51) Int. Cl. H01S 5/11; H01S 5/00; H01S 5/40; H01S 5/343

(52) U.S. Cl. CPC H01S 5/11; H01S 5/0064; H01S 5/0078; H01S 5/4012; H01S 5/343

(57) ABSTRACT

A semiconductor laser device is specified, the semiconductor laser device comprising an active layer having a main extension plane, a first cladding layer and a second cladding layer, the active layer being arranged between the first and second cladding layer in a direction perpendicular to the main extension plane, a light-outcoupling surface parallel to the main extension direction and arranged on a side of the second cladding layer opposite to the active layer, a photonic crystal layer arranged in the first cladding layer or in the second cladding layer, and an integrated optical element directly fixed to the light-outcoupling surface. Furthermore, a method for manufacturing a semiconductor laser device and a projection device are specified.

### FIELD

A semiconductor laser device, a method for manufacturing a semiconductor laser device, and a projection device are specified.

### BACKGROUND

Illumination systems for applications like, for instance, augmented reality (AR), virtual reality (VR) or head-up display (HUD), require laser light sources with high optical powers and a narrow optical linewidth. Stabilization of a narrow optical linewidth can be obtained by implementing an external-cavity set-up using, for example, a Bragg grating downstream a laser diode. When using an edge-emitting laser diode as laser light source, additionally a precollimation is required between the laser diode and the grating due to the high divergence angles in the slow axis direction and, even more, in the fast axis direction. Furthermore, in order to prevent optical feedback and ensuring a stable low linewidth, an optical isolator is often used downstream the output of a laser diode. Said additional components lead to a rather complex and bulky as well as rather expensive set-up.

At least one object of particular embodiments is to provide a semiconductor laser device. Further objects of particular embodiments are to provide a method for manufacturing a semiconductor laser device and to provide a projection device.

These objects are achieved by the subject-matter according to the independent claims. Advantageous embodiments and developments of the subject-matters are characterized in the dependent claims, and are also disclosed by the following description and the drawings.

### SUMMARY

According to at least one embodiment, a semiconductor laser device comprises at least one active layer which is intended and embodied to generate light in at least one active region during operation of the semiconductor laser device. Here and in the following, “light” preferably denotes electromagnetic radiation in an infrared to ultraviolet wavelength range. In particular, the active layer can be part of a semiconductor layer sequence comprising a plurality of semiconductor layers and can have a main extension plane perpendicular to an arrangement direction of the layers of the semiconductor layer sequence. The light generated in the active layer of the semiconductor layer sequence and especially in the active region during operation of the semiconductor laser device can be emitted via a light-outcoupling surface. In particular, the semiconductor laser device can be embodied as a semiconductor laser diode.

According to a further embodiment, the semiconductor laser device comprises an integrated optical element. Here and in the following, an “integrated optical element” means that the optical element is a constituent part of the semiconductor laser device and is fixedly connected with the semiconductor layer sequence. In particular, the integrated optical element can be directly fixed to the light-outcoupling surface. In other words, the optical element is not separate from the semiconductor layer sequence and, in particular, from the light-outcoupling surface, but forms an integral part of the semiconductor laser device that, under normal conditions, remains permanently on the light-outcoupling surface. Preferably, the integrated optical element is not intended to and, under normal operating conditions, cannot be removed from the light-outcoupling surface without destroying at least a part of the light-outcoupling surface and/or the optical element.

According to a further embodiment, the at least one active region of the semiconductor laser device has an aperture of more than 100 μm in diameter. In other words, the size of the region of the light-outcoupling surface from which light is emitted is designed to have a diameter of more than 100 μm. By designing such large aperture, the radiation characteristics of the emitted light are normally substantially diffraction limited, which can preferably result in an almost perfectly collimated beam. Under such circumstances it can be particularly advantageous to integrate the optical element into the semiconductor laser device, since no collimation optics are needed directly downstream of the light-outcoupling surface. Thus, integrating the optical element allows for a simple, compact and low cost approach, since, as described in the following, the integrated optical element can be directly attached to or directly processes on the light-outcoupling surface.

According to at least one further embodiment, in a method for manufacturing a semiconductor laser device a semiconductor layer sequence is provided, wherein the semiconductor layer sequence comprises an active layer and a light-outcoupling surface. An optical element is directly fixed to the light-outcoupling surface, so that the optical element forms an integrated optical element in the semiconductor laser device.

According to at least one further embodiment, a projection device comprises at least one semiconductor laser device. Preferably, the projection device can comprise more than one semiconductor laser device. Particularly preferably, the projection device can comprise two or more semiconductor laser devices.

The embodiments and features described above and in the following equally apply to the semiconductor laser device, to the method for manufacturing the semiconductor laser device and to the projection device.

According to a further embodiment, the active layer can have exactly one active region. The active region can at least partly be defined by a contact surface of one or more electrical contact layers with the semiconductor layer sequence, i.e., at least partly by a surface through which current is injected into the semiconductor layer sequence and thus into the active layer. Furthermore, the active region can at least partially be defined by structured semiconductor layers like, for instance, current-spreading and current-delimiting layers in the semiconductor layer sequence. Furthermore, the semiconductor laser device can have one or more reflective or partly reflective layers that can form an optical resonator and that can contribute to the definition of an active region.

The light-outcoupling surface and a rear surface opposite the light-outcoupling surface can, for instance, be surfaces that are at least partly and preferably substantially parallel to the main extension direction of the active layer, respectively. Suitable optical coatings or layers, in particular reflective or partially reflective layers or layer sequences, which can form an optical resonator for the light generated in the active layer as mentioned before, can form the light-outcoupling surface and/or the rear surface or can be applied in the vicinity of the light-outcoupling surface and/or in the vicinity of the rear surface.

Directions parallel to the main extension plane of the active region can, here and in the following, be denoted as the lateral directions. The arrangement direction of the layers of the semiconductor layer sequence on top of each other, i.e., a direction perpendicular to the main extension plane of the active layer, can, here and in the following, be denoted as vertical direction. Consequently, the semiconductor laser device can emit light during operation with a main emission direction along the vertical direction. The side of the semiconductor laser device from which light is emitted during operation can also be denoted as front side, whereas the side opposite the front side can be denoted as rear side. In other words, the light-outcoupling surface is situated on the front side, while the rear surface is situated on the rear side of the semiconductor laser device.

Furthermore, as mentioned above the semiconductor laser device can comprise electrical contact layers on the semiconductor layer sequence for applying an electrical current to the semiconductor layer sequence and, thus, to the active layer for operating the semiconductor laser device. In particular, a first electrical contact layer can be applied on the front side, and a second electrical contact layer can be applied on the rear side. If the light produced in the active layer is emitted through the first electrical contact layer, the first electrical contact layer can form the light-outcoupling surface of the semiconductor layer sequence. In this case, the first electrical contact layer can be preferably a continuous layer and can comprise or be made from a transparent conducting material like a transparent conductive oxide. Alternatively, the first electrical contact layer can be patterned. For example, the first electrical contact layer can be patterned to at least partly have a ring shape or form a grid. The light produced in the active layer during operation can be emitted from one or more regions that are not covered with material of the first electrical contact layer, so that the semiconductor layer sequence or a coating on the semiconductor layer sequence in such regions can form the light-outcoupling surface. In this case, the first electrical contact layer can for example comprise or be made of an oblique material like a metal or a metal layer stack. On the rear side, the second electrical contact layer can preferably be applied as continuous layer and can comprise or be made of an oblique material.

The optical element can be fixed to light-outcoupling surface by any method that can ensure, under normal conditions, a permanent connection between the light-outcoupling surface and the optical element. For instance, the integrated optical element can be adhered to the light-outcoupling surface, for example by a layer comprising or being made of a glue, a solder or a sinter material. Alternatively, the integrated optical element can be fixed to the light-outcoupling surface by a direct-bonding method, for instance direct wafer bonding. Furthermore, at least a part of the integrated optical element can be manufactured on the light-outcoupling surface. For instance, at least one layer of the integrated optical element can be directly applied to the light-outcoupling surface, for instance by a depositing process like an evaporation process or by spin coating. It can also be possible that the integrated optical element is completely manufactured on the light-outcoupling surface by performing all method steps for manufacturing the optical element on the light-outcoupling surface.

The semiconductor layer sequence can, in particular, be embodied as an epitaxial layer sequence, i.e., as an epitaxially grown semiconductor layer sequence. In this case, a plurality of semiconductor layers including the active layer can be grown on top of each other, wherein the semiconductor layers are based on a compound semiconductor material system, respectively.

The semiconductor layer sequence can be based on InAlGaN, for example. InAlGaN-based semiconductor layer sequences include in particular those in which the epitaxially produced semiconductor layer sequence generally comprises a layer sequence of different individual layers which contains at least one individual layer which comprises a material from the III-V compound semiconductor material system InₓAl_{y}Ga_{1-x-y}N—with 0≤x≤1, 0≤y≤1 and x+y≤1. In particular, the active layer can be based on such a material. Semiconductor layer sequences that have at least one active layer based on InAlGaN can, for example, emit electromagnetic radiation in an ultraviolet to green or even yellow wavelength range.

Alternatively or additionally, the semiconductor layer sequence can also be based on InAlGaP, i.e., the semiconductor layer sequence can have different individual layers, of which at least one individual layer, for instance the active layer, comprises a material made of the III-V compound semiconductor material system InₓAl_{y}Ga_{1-x-y}P with 0≤x≤1, 0≤y≤1 and x+y≤1. Semiconductor layer sequences which have at least one active layer based on InAlGaP can, for example, preferably emit electromagnetic radiation with one or more spectral components in a green to red wavelength range.

Alternatively or additionally, the semiconductor layer sequence can also comprise other III-V compound semiconductor material systems, such as an InAlGaAs-based material, or II-VI compound semiconductor material systems. In particular, an active layer comprising an InAlGaAs based material can be capable of producing electromagnetic radiation having one or more spectral components in a red to infrared wavelength range.

A II-VI compound semiconductor material may have at least one element from the second main group, such as Be, Mg, Ca, Sr, and one element from the sixth main group, such as O, S, Se. For example, the II-VI compound semiconductor materials include ZnO, ZnMgO, CdS, ZnCdS, MgBeO.

The active layer and, in particular, the semiconductor layer sequence with the active layer can be arranged on a substrate. The substrate may comprise a semiconductor material, such as a compound semiconductor material system mentioned above, or another material. In particular, the substrate can comprise or be made of sapphire, GaAs, GaP, GaN, InP, SiC, Si, Ge and/or a ceramic material as for instance SiN or AlN. For example, the substrate can be embodied as a growth substrate on which the semiconductor layer sequence is grown. The active layer and, in particular, a semiconductor layer sequence with the active layer can be grown on the growth substrate by means of an epitaxial process, for example by means of metal-organic vapor phase epitaxy (MOVPE) or molecular beam epitaxy (MBE), and furthermore be provided with electrical contacts. Moreover, it may also be possible that the growth substrate is removed after the growth process. In this case, the semiconductor layer sequence can, for example, also be transferred after growth to a substrate embodied as a carrier substrate.

The active layer can for example comprise a conventional pn junction, a double heterostructure, a single quantum well structure (SQW structure) or a multiple quantum well structure (MQW structure) for generating light. The semiconductor layer sequence may include other functional layers and functional regions in addition to the active layer, such as p- or n-doped carrier transport layers, i.e., electron or hole transport layers, highly doped p- or n-doped semiconductor contact layers, undoped or p-doped or n-doped confinement, cladding layers, waveguide layers, barrier layers, planarization layers, buffer layers, protective layers and/or electrical contact layers, and combinations thereof. Moreover, additional layers such as buffer layers, barrier layers and/or protective layers can be arranged also perpendicular to the growth direction of the semiconductor layer sequence, for instance around the semiconductor layer sequence on side surfaces of the semiconductor layer sequence.

In particular, the semiconductor laser device and, thus, the semiconductor layer sequence can comprise a first cladding layer and a second cladding layer. The active layer is arranged between the first and the second cladding layer in a direction perpendicular to the main extension plane, i.e., along the stacking direction of the semiconductor layer sequence which is the vertical direction. In particular, the light-outcoupling surface is arranged on a side of the second cladding layer opposite to the active layer. In other words, the semiconductor laser device comprises a semiconductor layer sequence having at least a first cladding layer, an active layer and a second cladding layer, wherein, during operation, light is emitted through the light-outcoupling surface that is situated over the second cladding layer as seen from the active layer. The first cladding layer is arranged between the rear surface and the active layer, and the second cladding layer is arranged between the active layer and the light-outcoupling surface.

According to a further embodiment, the semiconductor laser device comprises a photonic crystal layer with at least one photonic crystal structure. Due to the photonic crystal layer, the semiconductor laser device can also be denoted as photonic-crystal semiconductor laser device in the following.

Preferably, the photonic crystal layer is arranged in a cladding layer. Accordingly, the photonic crystal layer can be arranged in the first cladding layer or in the second cladding layer. Although in the following the semiconductor laser device is described having one photonic crystal layer, the semiconductor laser device can also comprise more than one photonic crystal layer, which can be arranged in the same or in different cladding layers and, thus, on the same side or on different sides as seen from the active layer. In case the semiconductor laser device comprises more than one photonic crystal layer, the photonic crystal layers can comprise the same or similar features or different features.

The photonic crystal layer comprises at least one photonic crystal structure that comprises a two-dimensional lattice-like matrix of discontinuities in the photonic crystal layer. In particular, the discontinuities are arranged next to each other along lateral directions so that the lattice-like matrix extends parallel to the main extension plane of the active layer. In particular, the photonic crystal layer comprises the discontinuities which have a first refractive index and which are formed as discrete regions in a medium with a second refractive index that is higher than the first refractive index. The medium surrounding the discontinuities can, in particular, be a semiconductor layer of the semiconductor layer sequence. The discontinuities are formed by a medium with the first refractive index and can be, for instance SiO₂ or air or another gas. In case of air or another gas, the discontinuities can be formed as holes in the material of the photonic crystal layer.

The photonic crystal layer can be a separate layer, meaning that the cladding layer with the photonic crystal layer comprises the photonic crystal layer as a sublayer and at least one additional sublayer that is different from the photonic crystal layer, for instance in regard to the material. Alternatively, the photonic crystal layer can be an integral part of a cladding layer, meaning that the cladding layer is formed by a semiconductor material and that that semiconductor material also surrounds the discontinuities.

In particular, the discontinuities can be cylindrical structures extending in the vertical direction and being distributed in lateral directions. The discontinuities and, thus, the photonic crystal layer can have a height, measured in the vertical direction, that is equal to or preferably smaller than a thickness, measured in the vertical direction, of the cladding layer in which the photonic crystal layer is arranged.

The matrix of the discontinuities can be arranged, for example, in a rectangular lattice, a hexagonal lattice or a rotational lattice. Also, an oblique lattice is possible. The size and distance of the discontinuities with respect to their closest neighbors is on the order of the wavelength of the light produced in the active layer.

The distribution, shape and size of the discontinuities can be regular or irregular. A regular size can mean that the discontinuities have a similar size. The size of a discontinuity can be, in particular, one or more chosen from a length, a width, a diameter and an area measured along one or more lateral directions. An irregular size can mean that the discontinuities have different sizes, in particular with respect to their respective closest neighbors. A regular shape can mean that all discontinuities have a similar shape, for instance a column-like shape with the same or substantially the same round or polygonal cross-section in a plane parallel to the main extension plane of the active layer. An irregular shape can mean that the discontinuities have different sizes, in particular with respect to their respective closest neighbors. A regular distribution can for instance mean that the discontinuities are arranged at similar distances with respect to their respective closest neighbors in the lattice-like structure. An irregular distribution can mean that the lattice-like matrix can be characterized by regularly distributed similar unit cells, each unit cell containing a discontinuity, wherein the positions of the discontinuities in the unit cells vary from unit cell to unit cell.

The photonic crystal layer provides an optical nanostructure having a periodic or nearly periodic refractive index distribution with dimensions nearly equal to the wavelength of the light produced in the active layer. In the semiconductor layer sequence light is amplified and diffracted by the photonic crystal layer arranged in the vicinity of the active layer. The wavelength of the emitted light depends on the properties of the photonic crystal structure, for instance on one or more of distribution, size and shape of the discontinuities and lattice constant of the matrix. The amplified light is output via the light-outcoupling surface as a laser beam in a direction perpendicular to the surface. Even with a large emission area, the photonic crystal semiconductor laser device can provide a narrow spot beam pattern, having a narrow beam spread angle and circular shape, and a narrow spectral linewidth.

According to a further embodiment, the semiconductor laser device has at least one first emission region and at least one second emission region arranged next to each other in a direction parallel to the main extension plane. In this case, the semiconductor laser device has at least two regions which are arranged laterally next to each other and which can be operated to emit light from the light-outcoupling surface. For example, the at least two emission regions can be operated independently from each other. Alternatively, the at least two emission regions can be operated simultaneously.

According to a further embodiment, the photonic crystal layer comprises a first photonic crystal structure in the first emission region and a second photonic crystal structure in the second emission region, wherein the first and the second photonic crystal structures are different. As described above, the wavelength of the light produced in the active layer and amplified in the semiconductor laser device depends on the properties of the photonic crystal structure. Consequently, having two different photonic crystal structures, the semiconductor laser device can produce and emit light with a first wavelength from the first emission region and light with a second wavelength different from the first wavelength in the second emission region. Thus, the semiconductor laser device can be configured as a multi-wavelength emitter emitting at least two light beams with different wavelengths. Preferably, the second wavelength can be slightly detuned with respect to the first wavelength. By overlapping the light beams of the first and second emission region, such detuning allows, in particular in a projection device, the reduction of interference effects and speckle that could be perceived by an observer. For example, the first emission region can emit light with a central wavelength λ, and the second emission region can emit light with a central wavelength λ+Δλ. For instance, Δλ, can be equal to or greater than 2 nm and less than or equal to 10 nm or less than or equal to 5 nm. In particular, both the light emitted by the first emission region and the light emitted by the second emission region can have a spectral width, for example an FWHM (full width at half maximum) of several nm, for instance less than 10 nm or less than 5 nm. Preferably, Δλ, can be equal to or greater than the FWHM.

In particular, the first photonic crystal structure can comprise a two-dimensional lattice-like first matrix of discontinuities in the photonic crystal layer and the second photonic crystal structure can comprise a two-dimensional lattice-like second matrix of discontinuities in the photonic crystal layer, wherein the first and the second two-dimensional matrices differ in regard to one or more parameters chosen from lattice constant, density of discontinuities, mean size of discontinuities, material of discontinuities. The mean size of the discontinuities of each of the photonic crystal structures can be, for instance, an average diameter or an average area, measured in a plane parallel to the main extension plane of the active layer, of the discontinuities of the respective photonic crystal structure.

Furthermore, the semiconductor laser device can further comprise at least one third emission region, wherein the photonic crystal layer comprises a third photonic crystal structure in the third emission region and wherein the third photonic crystal structure is different to both the first and the second photonic crystal structures. Consequently, the third emission region can produce and emit light with a third wavelength that is different from the first and second wavelength. Moreover, the semiconductor laser device can have more than three emission regions emitting light with different wavelengths.

According to a further embodiment, the semiconductor laser device can comprise a plurality of first emission regions and a plurality of second active regions. For example, the semiconductor laser device can comprise n×m emission regions with n, m being natural numbers greater than 1, respectively, wherein n denotes the number of different wavelengths and m denotes the number of emission regions per wavelength.

According to a further embodiment, the integrated optical element comprises one or more optical functions like wavelength filtering, polarization filtering, polarization conversion, optical isolation. Accordingly, the integrated optical element can comprise or form one or more elements chosen from a wavelength filter, a polarization filter, a polarization converter, an optical isolator. Preferred embodiments resulting in one or more of said optical functions are described in the following.

The integrated optical element can comprise or be a wavelength filter. The wavelength filter can comprise a grating structure having, preferably as seen along the light emission direction, alternately stacked regions with different refractive indices. Particularly preferably, the integrated optical element comprises a volume Bragg grating (VBG). The volume Bragg grating comprises a transparent medium having a periodic modulation of the refractive index in some region. In other words, the volume Bragg grating is a volume hologram. The refractive index modulation can be produced for example by irradiating a photosensitive material with ultraviolet light in the spatial shape of a standing wave pattern. The photosensitive material can, for example, comprise or be a photosensitive glass, like silica which can contain one or more dopants, or a photosensitive polymer. The volume Bragg grating can be manufactured separately and fixed to the light-outcoupling surface. Preferably, the photosensitive material can be applied as film to the light-outcoupling surface, for instance by spin-coating or other suitable deposition method. Afterwards, the VBG structure can be written into the applied film by holographic writing.

The integrated optical element can comprise or be a polarization filter. In other words, the integrated optical element can comprise or be a polarizer, for instance for transmitting light with a linear or circular polarization. For instance, the polarizer can comprise or be made from a metal grid. Preferably, the polarizer is directly manufactured on the light-outcoupling surface, for instance by depositing the metal grid on the light-outcoupling surface. Furthermore, the integrated optical element can comprise a polarization-effecting material between two polarizers. Preferably, a first polarizer is directly manufactured on the light-outcoupling surface.

Particularly preferably, the integrated optical element can comprise or be an optical isolator, having a first polarizer and a second polarizer, the second polarizer being rotated by 45° with respect to the first polarizer, wherein a polarization rotating element like a Faraday element is arranged between the first and second polarizer. Materials for the Faraday element can be, for example, terbium doped borosilicate glass, terbium gallium garnets, yttrium iron garnets or, preferably, bismuth-substituted rare-earth iron garnets. Alternatively or additionally, the integrated optical element can comprise a polarization converter having a quarter-wave-plate element, for instance comprising a birefringent material, between the first and second polarizer.

In particular, the integrated optical element can comprise or be formed as a plate element with an input surface facing the light-outcoupling surface and an output surface facing away from the light-outcoupling surface. The plate element can have one or more of the optical functions and can be embodied as described before. The input surface can be directly mounted onto the light-outcoupling surface. Particularly preferably, the input surface can be formed by manufacturing at least a part of the plate element directly on the light-outcoupling surface.

Alternatively, the integrated optical element comprises a spacer element on the input surface of the plate element, wherein the spacer element is directly mounted onto the light-outcoupling surface. For instance, the spacer element can have a plate-like form or a frame-like form. Preferably, the spacer element comprises a transparent material such as glass and/or plastic or is made of glass and/or plastic. Particularly preferably, the spacer is directly manufactured on the light-outcoupling surface, for instance by spin coating and, if applicable, by patterning and curing the applied material. In case the spacer is formed as frame, the aperture of the semiconductor laser device can be surrounded by the frame. Between the plate element and the light-outcoupling surface can be a gap that is surrounded by the frame and that can contain a gas, like air or an inert gas, or a vacuum.

According to a further embodiment, the semiconductor laser device comprises at least one first emission region and at least one second emission region arranged next to each other in a direction parallel to the main extension plane as described above. The integrated optical element can be arranged on both the at least one first emission region and the at least one second emission region, thereby covering both the at least one first emission region and the at least one second emission region. Alternatively, a first integrated optical element can be arranged on the at least one first emission region and a second integrated optical element can be arranged on the at least one second emission region. The first and second integrated optical elements can be embodied as described before and can be similar or different to each other. For instance, the at least one first emission region and the at least one second emission region can emit light with different wavelengths, wherein the first integrated optical element is adapted to the wavelength of light emitted by the first emission region and the second integrated optical element is adapted to the wavelength of light emitted by the second emission region. It can also be possible that the first and second emission region are embodied similarly and the first and second integrated optical element are embodied as different wavelength filters. For instance, the first and second integrated optical element can be embodied as VBGs having different properties so that the first emission region is forced to emit light with a first wavelength and the second emission region is forced to emit light with a second wavelength that is different from the first wavelength.

According to a further embodiment, the projection device comprises a plurality of semiconductor laser devices, wherein the plurality of semiconductor laser devices comprises at least a first semiconductor laser device emitting, during operation, light with a first color, and at least a second semiconductor laser device emitting, during operation, light with a second color being different from the first color. Here and in the following, a first color being different from a second color means that the first color and the second color can be perceived as different by a human observer. For instance, the first and the second color can each have a central wavelength which are separated by more than 50 nm or more than 100 nm. For example, the first color can be red and the second color can be green.

In addition, the projection device can comprise at least one third semiconductor laser device emitting, during operation, light with a third color that is different from the first and second color. For example, the first color can be red, the second color can be green and the third color can be blue, so that the projection device can be an RGB projection device.

According to a further embodiment, the projection device comprises an optics system arranged directly downstream of the semiconductor laser devices for directing the emitted light onto an image plane. As described above, the semiconductor laser devices can preferably emit light beams with a very low beam divergence, for example of much less than 1°, with the emission regions having diameters of more than 100 μm and preferably more than 200 μm. Thus, since the semiconductor laser devices provide already collimated light and comprise an integrated optical element, the optics system can be simplified in comparison to usual projection systems based, for instance, on edge-emitting laser diodes, and can be, in particular, free of any collimating optics and polarization-modifying optics arranged downstream of the semiconductor laser devices.

According to a further embodiment, the optics system comprises one or more scanning mirrors, i.e., one or more movable mirrors that can be used to scan the light beams of the photonic crystal semiconductor laser devices over an image region. Preferably, the one or more scanning mirrors are based on MEMS (microelectromechanical system) technology.

According to a further embodiment, the optics system comprises a beam combining element. The beam combining element can comprise a lens and/or a beam deflection element. In particular, the beam combining element can be arranged directly downstream of the semiconductor laser devices.

The semiconductor laser device, alone or in the projection device, can be used in various applications besides AR/VR applications and HUD applications. For instance, the semiconductor laser device can be used in Raman-spectroscopy-related applications which can use, for instance, pulsed visible and/or near-infrared (NIR) emitting semiconductor laser devices that can provide, in addition to a very long coherence and low divergence, the following advantages: Due to the pulsing, fluorescence can be avoided, while a substantial signal can be achieved. The semiconductor laser devices can provide the required linewidths of less than 1 MHz and do not drift more than a few picometers over time and over a temperature range of several degrees Celsius. Furthermore, side mode suppression in a range more than 100 μm from the main emission peak and a spectral purity of more than 60 dB can be achieved. A diffraction limited TEM00 mode emitted by the semiconductor laser devices offers an optimum spatial resolution that is needed for Raman spectroscopy. Furthermore, low power fluctuations of less than 2-3% can be provided by the semiconductor laser devices. Moreover, optical feedback effects that can induce power and noise instabilities and that are serious issues for Raman spectroscopy can be overcome by the integrated optical element, leading to a very compact design.

Furthermore, for hyperspectral imaging in the infrared the semiconductor laser device can provide a superior performance compared to usual wavelength-tuned laser diodes in terms of power, toplooker architecture, wavelength stability and diffraction limited collimation and coherence. Moreover, the semiconductor laser device can be used as light source for laser cooling and trapping, for instance in ion traps, since the semiconductor laser device can provide a stable single-wavelength emission with diffraction limited coherence and collimation and can thus be an ideal compact and affordable light source.

Further features, advantages and expediencies will become apparent from the following description of exemplary embodiments in conjunction with the figures.

### BRIEF DESCRIPTION OF THE DRAWINGS

FIGS. 1A and 1B show schematic illustrations of a semiconductor laser device and a method for manufacturing a semiconductor laser device according to several embodiments;

FIGS. 2A to 2C show schematic illustrations of a semiconductor laser device according to further embodiments;

FIGS. 3A to 3C show schematic illustrations of partial views of a semiconductor laser device according to further embodiments;

FIGS. 4A and 4B show schematic illustrations of partial views of a semiconductor laser device according to further embodiments;

FIGS. 5A and 5B show schematic illustrations of partial views of a semiconductor laser device according to further embodiments;

FIG. 6 shows a schematic illustration of a projection device according to a further embodiment;

FIGS. 7A to 7C show schematic illustrations of a p semiconductor laser device and a projection device according to further embodiments.

### DETAILED DESCRIPTION

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

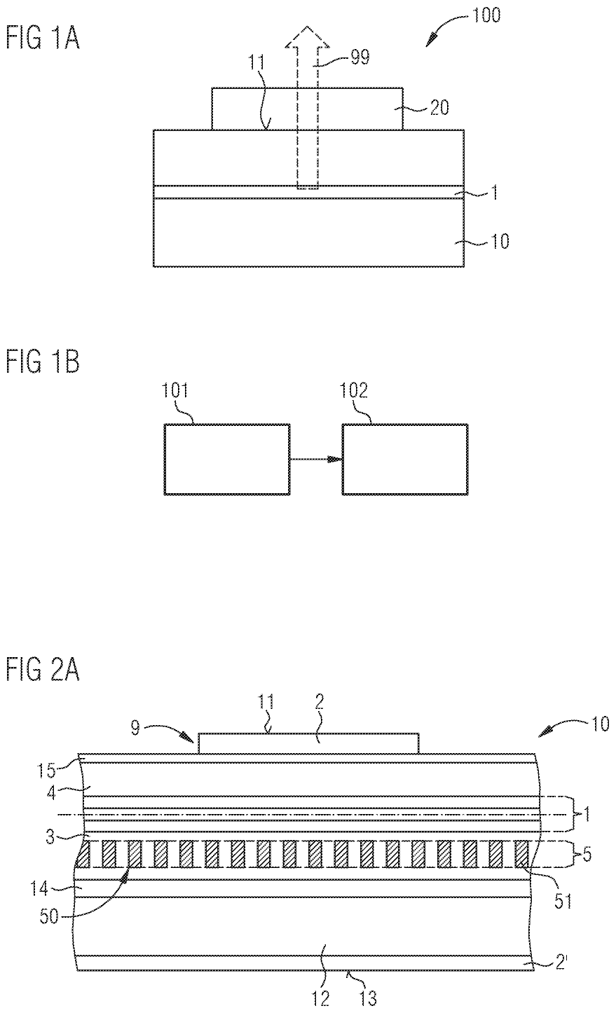

FIGS. 1A and 1B show schematic illustrations of an embodiment of a semiconductor laser device 100 and a method for manufacturing the semiconductor laser device 100.

As shown in FIG. 1A, the semiconductor laser device 100 comprises an active layer 1 that is intended and embodied to generate light in at least one active region during operation of the semiconductor laser device 100. The emitted light with its main radiation emission direction is indicated by the arrow labelled by the reference numeral 99 in FIG. 1A.

The active layer 1 is a part of a semiconductor layer sequence 10 comprising a plurality of semiconductor layers and has a main extension plane perpendicular to an arrangement direction of the layers of the semiconductor layer sequence. In particular, the semiconductor laser device 100 is embodied as a semiconductor laser diode that has a light-outcoupling surface 11. The light 99 generated in the active layer 1 of the semiconductor layer sequence 10 during operation of the semiconductor laser device 100 is emitted via the light-outcoupling surface 11.

Furthermore, the semiconductor laser device 100 comprises an integrated optical element 20 that is directly fixed to the light-outcoupling surface 11. Light 99 emitted by the active layer 1 during operation is emitted from the light-outcoupling surface 11 through the integrated optical element 20.

As explained above in the general part, the integrated optical element 20 is an integral part of the semiconductor laser device 100 and is fixedly connected to the semiconductor layer sequence 10. The optical element 20 is fixed to light-outcoupling surface 11 in such way that, under normal conditions, the light-outcoupling surface 11 and the optical element 20 are permanently connected with each other and that the integrated optical element is not intended to and, under normal operating conditions, cannot be removed from the light-outcoupling surface 11 without destroying at least a part of the light-outcoupling surface 11 and/or the optical element 20.

For manufacturing the semiconductor laser device 100 the semiconductor layer sequence 11 is provided in a first method step 101, as indicated in FIG. 1B, wherein the semiconductor layer sequence 11 comprises the active layer 1 and the light-outcoupling surface 11. An optical element is directly fixed to the light-outcoupling surface, so that the optical element forms the integrated optical element 20 in the semiconductor laser device 100, as indicated in method step 102.

For instance, the integrated optical element 20 can be separately manufactured and can be fixed to the light-outcoupling surface 11, for example by a layer comprising or being made of a glue, a solder or a sinter material. Alternatively, the integrated optical element 20 can be fixed to the light-outcoupling surface 11 by a direct-bonding method, for instance direct wafer bonding, without using an intermediate layer. Furthermore, at least a part of the integrated optical element 20 can be manufactured on the light-outcoupling surface 11. For instance, at least one layer or element of the integrated optical element 20 can be directly applied to the light-outcoupling surface 11, for instance by a depositing process like an evaporation process or spin coating. It can also be possible that the integrated optical element 20 is completely manufactured on the light-outcoupling surface 11 by performing all method steps for manufacturing the optical element on the light-outcoupling surface.

The semiconductor laser device 100 is preferably manufactured in a wafer-based process, wherein a plurality of laser device units comprising the semiconductor layer sequence are manufactured by a growth process on a common growth substrate, thereby producing a laser device unit compound. Furthermore, an integral optical element 20 can be fixed to the light-outcoupling surface of each of the plurality of laser device units while still being connected to each other in the compound. Afterwards, the compound can be singulated to separate the semiconductor laser devices from each other.

Further features and embodiments of the semiconductor laser device and the method for manufacturing the semiconductor laser device are described in connection with the following figures.

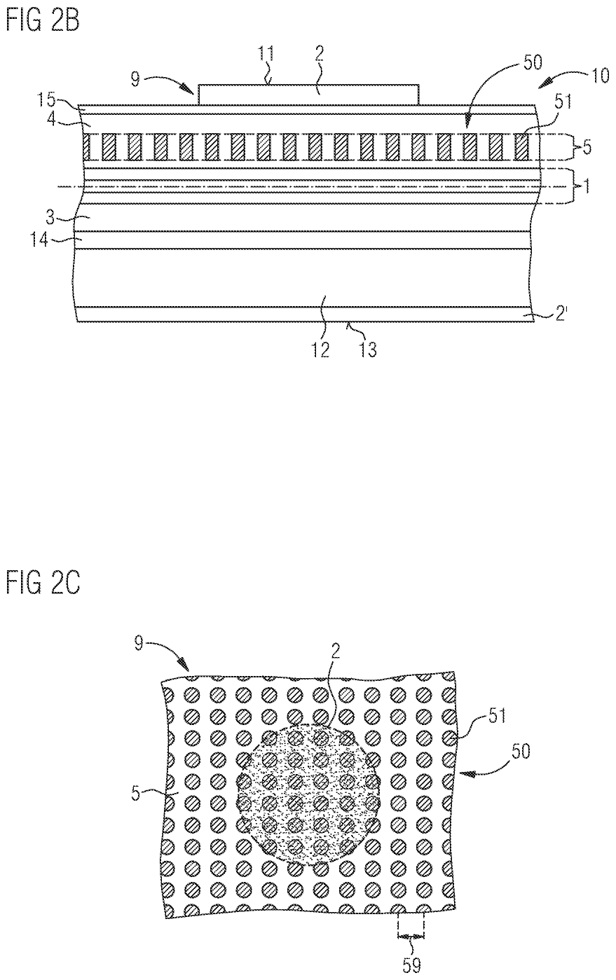

FIGS. 2A to 2C show schematic illustrations of the semiconductor layer sequence 10 of the semiconductor laser device 100 shown in FIG. 1A. In particular, the semiconductor laser device comprises a photonic crystal layer with at least one photonic crystal structure, thus the semiconductor laser device can also be referred to as photonic-crystal semiconductor laser device 100 in the following. FIGS. 2A and 2B show sectional views of the photonic crystal semiconductor laser device 100 and FIG. 2C shows a sectional view of the photonic crystal structure 50 of the photonic crystal semiconductor laser device 100, wherein in FIG. 2C a position of an electrical contact layer is also indicated. The following description equally applies to all FIGS. 2A to 2C.

As already described in connection with FIG. 1A, the semiconductor laser device 100 comprises the active layer 1 for generating light 99 in an active region during operation of the semiconductor laser device 100. The active region determines an emission region 9 of the semiconductor laser device 100, wherein the emission region 9 can be configured to emit a light beam having an aperture with a diameter of more than 100 μm or, preferably, more than 200 μm. Consequently, the radiation characteristics of the emitted light can be substantially diffraction limited, resulting, preferably, in an almost perfectly collimated beam.

The active layer 1 that is a part of the semiconductor layer sequence 10 can comprise a plurality of semiconductor layers, as indicated in FIGS. 2A and 2B, and has a main extension plane, indicated by the dot-dashed line, perpendicular to an arrangement direction of the layers of the semiconductor layer sequence 10. Directions parallel to the main extension plane of the active layer 1 are denoted as lateral directions, while the arrangement direction of the layers of the semiconductor layer sequence 10 can be denoted as vertical direction. The light generated in the active layer 1 and especially in the active region during operation of the photonic crystal semiconductor laser diode 100 can be emitted via the light-outcoupling surface 11, with a main radiation emission direction along the vertical direction.

For example, the active layer 1 can have exactly one active region and can comprise, for instance, an MQW structure for generating light. The active region can at least partly be defined by a contact surface of one or more electrical contact layers 2, 2′ with the semiconductor layer sequence 10, i.e., at least partly by a surface through which current is injected into the semiconductor layer sequence 10 and thus into the active layer 1. Although not shown in the figures, the active region can additionally be defined at least partially by structured semiconductor layers like, for instance, current-spreading and/or current-delimiting layers in the semiconductor layer sequence 10. Moreover, the photonic crystal semiconductor laser device 100 can have one or more reflective layers that can contribute to the definition of an active region.

The semiconductor layer sequence 10 can, in particular, be epitaxially grown. The semiconductor layers of the semiconductor layer sequence 10 can be arranged on a substrate 12 and can comprise a first cladding layer 3 and a second cladding layer 4. The active layer 1 is arranged between the first and the second cladding layer 3, 4 in a direction perpendicular to the main extension plane, i.e., along the vertical direction. The light-outcoupling surface 11 is arranged on a side of the second cladding layer 4 opposite to the active layer 1. The first cladding layer 3 is arranged between a rear surface 13, which can be a mounting surface of the photonic crystal semiconductor laser device 100, and the active layer 1, and the second cladding layer 4 is arranged between the active layer 1 and the light-outcoupling surface 11.

The semiconductor layer sequence 10 can comprise further semiconductor layers like, for example, a buffer layer 14 and a semiconductor contact layer 15 as well as other semiconductor layers (not shown) like waveguide layers. The layers of the semiconductor layer sequence 10 can be based on a III-V compound semiconductor material system and, furthermore, can comprise further features as described above in the general part.

The semiconductor layer sequence 10 further comprises a photonic crystal layer 5 with a photonic crystal structure 50. The photonic crystal 5 layer is preferably arranged in one of the cladding layers 3, 4. Accordingly, the photonic crystal layer 5 can be arranged in the first cladding layer 3 as shown in FIG. 2A or in the second cladding layer 4 as shown in FIG. 2B. Although here and in the following the semiconductor laser device 100 is described having exactly one photonic crystal layer 5, the photonic crystal semiconductor laser device 100 can also comprise more than one photonic crystal layer, which can be arranged in the same or in different cladding layers 3, 4 and, thus, on the same side or on different sides as seen from the active layer 1. In case the photonic crystal semiconductor laser device 100 comprises more than one photonic crystal layer, the photonic crystal layers can comprise the same or similar features or different features.

The photonic crystal structure 50 comprises a two-dimensional lattice-like matrix of discontinuities 51 in the photonic crystal layer 5 as shown in FIG. 2C. The discontinuities 51 are formed by discrete cylindrical structures extending in the vertical direction and are distributed in lateral directions in the photonic crystal layer 5. The discontinuities 51 and, thus, the photonic crystal layer 5 can have a height, measured in the vertical direction, that is equal to or preferably smaller than a thickness, measured in the vertical direction, of the cladding layer 3, 4 in which the photonic crystal layer 5 is arranged.

The matrix of the discontinuities 51 can be arranged, for example, in a rectangular lattice as shown in FIG. 2C. Alternatively, other lattice structures are possible, for instance a hexagonal lattice, a rotational lattice or an oblique lattice. The size and distance of the discontinuities 51 with respect to their closest neighbors is on the order of the wavelength of the light produced in the active layer 1.

The discontinuities 51 have a first refractive index, whereas the medium surrounding the discontinuities 51, i.e., the material of the photonic crystal layer 5, has a second refractive index that is different from the first refractive index. Preferably, the second refractive index is greater than the first refractive index. The medium surrounding the discontinuities 51, i.e., the bulk material of the photonic crystal layer 5, can, in particular, be formed of a semiconductor material of the semiconductor layer sequence 10. The discontinuities 51 can comprise or be made of, for instance, SiO₂ or air or another gas. In case of air or another gas, the discontinuities 51 can be formed by holes in the material of the photonic crystal layer 5.

The photonic crystal layer 5 can be a separate layer, meaning that the cladding layer 3, 4 with the photonic crystal layer 5 comprises the photonic crystal layer 5 as sublayer, as indicated by the dashed lines in FIGS. 2A and 2B, and at least one additional sublayer that is different from the photonic crystal layer, for instance in regard to the material. Alternatively, the photonic crystal layer 5 can be an integral part of a cladding layer 3, 4, meaning that the cladding layer 3, 4 including the photonic crystal layer 5 and the material of the photonic crystal layer 5 surrounding the discontinuities 51 are the same material.

The distribution, shape and size of the discontinuities 51 can be regular, as shown in FIGS. 2A to 2C, or irregular. A regular size, as shown for example in FIG. 2C, can mean that the discontinuities 51 have a substantially similar size, which can be, in particular, one or more or all chosen from a length, a width, a diameter and an area measured along one or more lateral directions. An irregular size can mean that the discontinuities have different sizes, in particular with respect to their respective closest neighbors. A regular shape, as shown in FIG. 2C, can mean that all discontinuities 51 have a similar shape, for instance a column-like shape with a round or polygonal cross-section in a plane parallel to the main extension plane of the active layer. An irregular shape can mean that the discontinuities have different sizes, in particular with respect to their respective closest neighbors. A regular distribution can for instance mean that the discontinuities are arranged at similar distances with respect to the respective closest neighbors in the lattice-like structure. Here, the discontinuities 51 can be arranged in a lattice-like manner with a lattice constant 59. An irregular distribution can mean that the lattice-like matrix can be characterized by regularly distributed similar unit cells with a lattice constant, each unit cell containing a discontinuity, wherein the positions of the discontinuities in the unit cells vary from unit cell to unit cell.

The photonic crystal layer 5 provides an optical nanostructure having a periodic or nearly periodic refractive index distribution with dimensions nearly equal to the wavelength of the light produced in the active layer 1. In the semiconductor layer sequence 10 light is amplified and diffracted by the photonic crystal layer 5 arranged in the vicinity of the active layer 1. Particularly preferably, the photonic crystal layer 5 is arranged close to the active layer 1. For example, an additional reflector layer below the active layer 1 can enhance the output power of the light produced in the semiconductor layer sequence 10. However, it can also be possible that no additional resonator or mirror is necessary.

The photonic crystal layer 5 and, in particular, the photonic crystal structure 50, i.e., the size, shape and distribution of the discontinuities 51, determine the emission characteristic. In other words, the wavelength of the emitted light 99 can be tuned by the properties of the photonic crystal structure 50, for instance by one or more of distribution, size and shape of the discontinuities 51 and lattice constant 59 of the matrix. The amplified light is output via the light-outcoupling surface 11 as a laser beam. Even with a large area of the active region and, thus, the emission region 9, which can be more than 100 μm or more than 200 μm in diameter, the photonic crystal semiconductor laser device 100 can provide a narrow spot beam pattern, having a narrow beam spread angle of less than 1° and with a circular shape, and a narrow spectral linewidth.

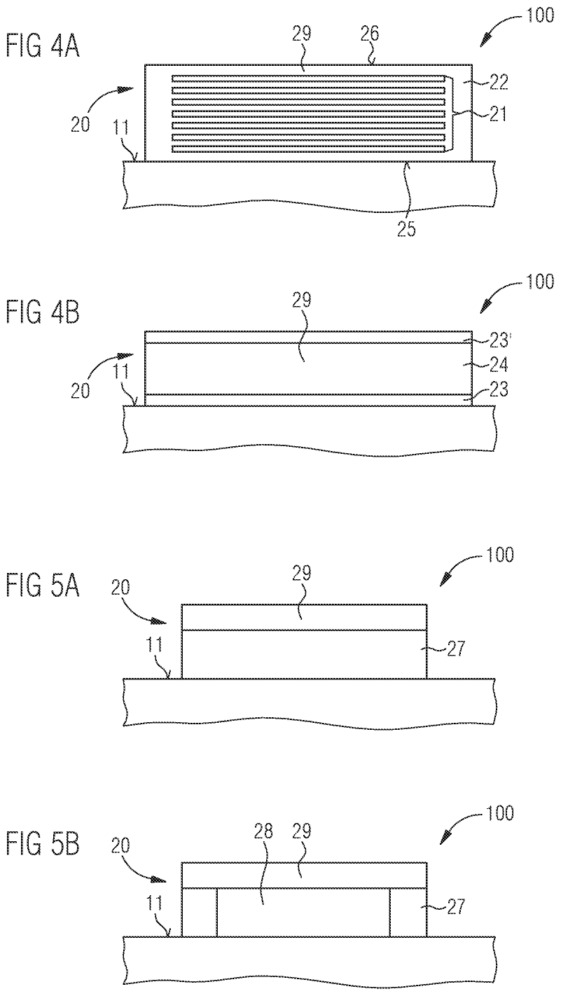

The electrical contact layers 2 on the light-outcoupling surface 11 and on the rear side of the semiconductor layer sequence 11 can be applied continuously or patterned. In the shown embodiment, a first electrical contact layer 2 on the light-outcoupling surface 11 is formed in a disk shape for defining the active region in the active layer 1, while a second electrical contact layer 2′ on the rear side is applied continuously over a large area. However, depending on the electrical contact layer 2 on the light-outcoupling surface 10 the light-outcoupling surface 10 to which the integrated optical element 20 is fixed can vary, as shown in FIGS. 4A to 4C.

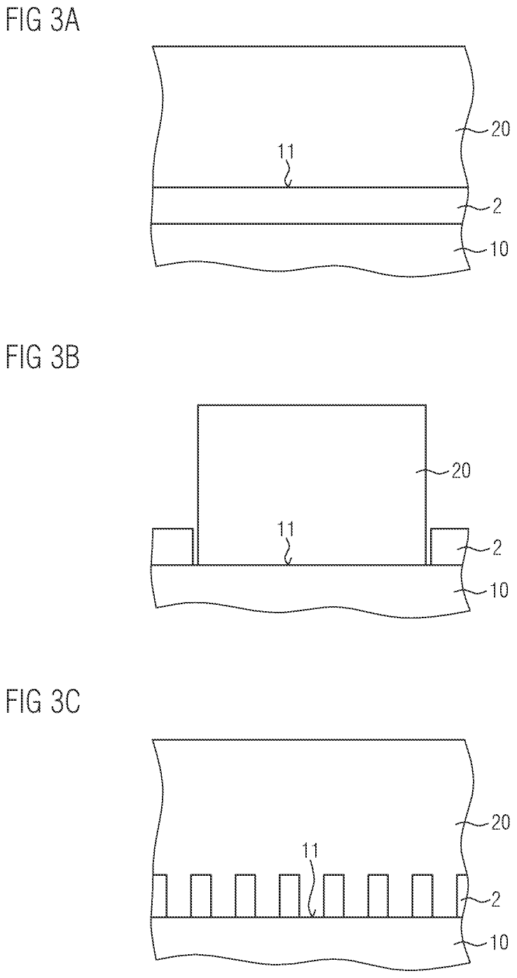

As shown in FIG. 3A, f the light produced in the active layer 1 is emitted through the first electrical contact layer 2, the first electrical contact layer 2 can form the light-outcoupling surface 11 of the semiconductor layer sequence 10 as also indicated in FIGS. 2A and 2B. Preferably, the first electrical contact layer 2 can comprise or be made from a transparent conducting material like a transparent conductive oxide. The integrated optical element 20 is directly fixed to the first electrical contact layer 2. The electrical contact layer 2 can comprise conductor track or similar that leads out from under the integrated optical element and that is not covered by the integrated optical element 20 so that the first electrical contact layer 2 can be connected to an external current source.

Alternatively, the first electrical contact layer 2 can be patterned as indicated in FIGS. 4B and 4C. For example, the first electrical contact layer 2 can be patterned to at least partly have a ring shape (FIG. 3B) or form a grid (FIG. 3C). The light produced in the active layer during operation can be emitted from one or more regions that are not covered with material of the first electrical contact layer 2, so that the semiconductor layer sequence 10 forms the light-outcoupling surface 11. In this case, the first electrical contact layer 2 can comprise or be made of an oblique material like a metal or a metal layer stack.

The integrated optical element 20 comprises one or more optical functions like wavelength filtering, polarization filtering, polarization conversion, optical isolation and can comprise one or more chosen from a wavelength filter, a polarization filter, polarization converter, optical isolator.

As shown in FIG. 4A, the integrated optical element 20 can comprise or be a wavelength filter. The wavelength filter can comprise a grating structure 21 having, along the light emission direction, alternately stacked regions with different refractive indices. Particularly preferably, the integrated optical element comprises a volume Bragg grating (VBG). The volume Bragg grating comprises a photosensitive transparent material 22 having a periodic modulation of the refractive index formed by the grating structure 21 that can be produced, for example, by irradiating the material 22 with ultraviolet light in the spatial shape of a standing wave pattern. The photosensitive material 22 can, for example, comprise or be a photosensitive glass, like silica which can contain one or more dopants, or a photosensitive polymer. The volume Bragg grating can be manufactured separately and fixed to the light-outcoupling surface 11. Preferably, the photosensitive material 22 can be applied as film to the light-outcoupling surface 11, for instance by spin-coating. Afterwards, the grating structure 21 can be written into the applied film formed by the material 22 by holographic writing.

The combination of a photonic crystal laser structure in the semiconductor layer sequence with its diffraction limited collimated beam with an integrated VBG can lead to an external-cavity-laser-like structure with a stable and narrow optical emission, but without additional optics downstream the laser diode, so that a compact device can be achieved and no active alignment process is necessary.

Furthermore, the integrated optical element 20 can comprise or be a polarization filter, for example a polarizer comprising or being made from a metal grid. For instance, as shown in FIG. 4B, the integrated optical element 20 can comprise a first polarizer 23, a second polarizer 23′ and a polarization-effecting material 24 between the two polarizers 23, 23′. Preferably, at least the first polarizer 23 is directly manufactured on the light-outcoupling surface 11, for instance by depositing a metal grid on the light-outcoupling surface 11. The material 24 and the second polarizer 23′ can preferably also be manufactured by depositing the respective material.

For example, the integrated optical element 20 can be an optical isolator, having the first polarizer 23 and the second polarizer 23′ that is rotated by 45° with respect to the first polarizer 23, wherein a polarization rotating material 24 like a Faraday element is arranged between the first and second polarizer 23, 23′. Materials for the Faraday element can be, for example, bismuth-substituted rare-earth iron garnets. For instance, a thickness of about 480 μm can be suitable for a wavelength of 1550 nm. Consequently, the semiconductor laser device 100 can have a built-in optical isolator that can prevent optical feedback and ensure a stable low linewidth without the need for an additional external optical isolator.

For some application, linear polarized light is difficult to operate with, for instance because it causes speckle in projection or AR/VR applications. Thus, alternatively or additionally, the integrated optical element 20 can comprise as material 24 a polarization converter having a quarter-wave-plate element between the first and second polarizer 23, 23′. This integrated on-chip-setup can transform linear polarized light emitted from the semiconductor layer sequence directly into circularly polarized light and also act simultaneously as an optical isolator. The quarter-wave-plate element can comprise or be a birefringent material comprising or formed by a glass foil or an ultra thin glass, crystal or plastic plate, for instance having a thickness of less than 100 μm, making on-chip integration easy as no magnetic field is needed.

Thus, the integrated optical element 20 can provide a compact solution of a laser source with the required optical isolation and/or polarization conversion within one small and compact device and without active alignment and additional optics.

As shown in FIGS. 4A and 4B, the integrated optical element 20 can comprise or be formed as a plate element 29 with an input surface 25 facing the light-outcoupling surface 11 and an output surface 26 facing away from the light-outcoupling surface 11. The plate element 29 can have one or more of the optical functions as described before. As described before, the input surface 25 can be directly mounted onto the light-outcoupling surface 11. Particularly preferably, the input surface 25 can be formed by manufacturing at least a part of the integrated optical element 20 directly on the light-outcoupling surface 11.

Alternatively, the integrated optical element 20 can comprise a spacer element 27 on the input surface 25 of the plate element 29 as shown in FIGS. 5A and 5B, wherein the spacer element 27 is directly mounted onto the light-outcoupling surface 11. For instance, the spacer element 27 can have a plate-like form (FIG. 5A) or a frame-like form (5B). Preferably, the spacer element 27 comprises glass or is made of glass. Particularly preferably, the spacer element 27 is directly manufactured on the light-outcoupling surface 11, for instance by spin coating and, if applicable, by patterning and curing the applied material. In case the spacer element 27 is formed as frame as shown in FIG. 5B, the emitted light beam of the semiconductor laser device can be laterally surrounded by the frame. Between the plate element 29 and the light-outcoupling surface 11 can be a gap 28 that is surrounded by the frame and that can contain a gas like air or an inert gas or a vacuum.

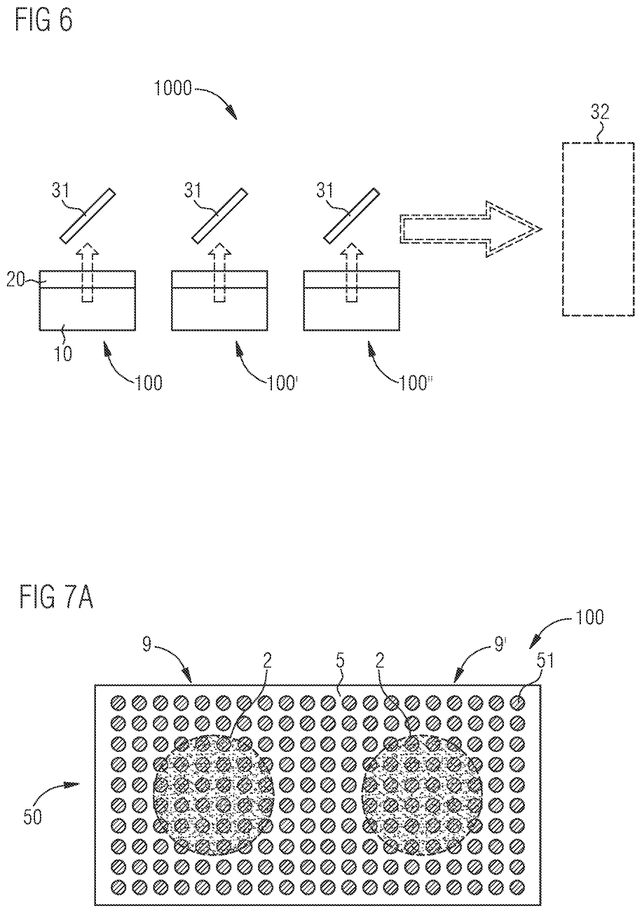

In FIG. 6 a projection device 1000 is shown, which comprises at least one photonic crystal semiconductor laser device 100 and, preferably, a plurality of semiconductor laser devices 100 as described in connection with any of the foregoing embodiments. For instance, the projection device 1000 can have three photonic crystal semiconductor laser devices 100, 100′, 100″ as shown in FIG. 6.

Each of the photonic crystal semiconductor laser devices 100, 100′, 100″ of the projection device 1000 emits light with a certain color that is preferably different from the colors of the other respective photonic crystal semiconductor laser devices 100, 100′, 100″. Accordingly, the projection device 1000 comprises a plurality of photonic crystal semiconductor laser devices 100, 100′, 100″, wherein the plurality of photonic crystal semiconductor laser devices 100, 100′, 100″ comprises at least a first photonic crystal semiconductor laser device 100 emitting, during operation, light with a first color, at least a second photonic crystal semiconductor laser device 100′ emitting, during operation, light with a second color being different form the first color, and at least a third photonic crystal semiconductor laser device 100″ emitting, during operation, light with a third color being different form the first and second color. For example, the first color can be red, the second color can be green and the third color can be blue, so that the projection device 1000 can be an RGB projector. The projection device 1000 can preferably be used in consumer, industry and automotive applications. For instance, the projection device 1000 can be implemented in a virtual reality (VR) or augmented reality (AR) projection system.

The projection device comprises an optics system arranged directly downstream of the semiconductor laser devices 100, 100′, 100″ for directing the emitted light onto an image plane. As described above, the semiconductor laser devices 100, 100′, 100″ can preferably emit light beams with a very low beam divergence, for example of much less than 1°, with the emission regions having diameters of more than 100 μm and preferably more than 200 μm. Thus, since the semiconductor laser devices 100, 100′, 100″ provide already collimated light and each comprise an integrated optical element 20, which can, for instance, comprise or be an optical isolator and/or a wavelength filter, the optics system can be simplified in comparison to usual projection systems based, for instance, on edge-emitting laser diodes, and can be, in particular, free of any collimating optics and polarization-modifying optics arranged downstream of the semiconductor laser devices. For instance, the optics system can comprise beam combining elements 31 and one or more scanning mirrors 32, i.e., one or more movable mirrors that can be used to scan the light beams of the photonic crystal semiconductor laser devices 100, 100′, 100″ over an image region. Preferably, the one or more scanning mirrors are based on MEMS (microelectromechanical system) technology. Alternatively or additionally, the light of the semiconductor laser devices 100, 100′, 100″ can be coupled into a lightguide or fiber optics, onto an LCoS (liquid crystal on silicon) or onto a DMD (digital micro-mirror device).

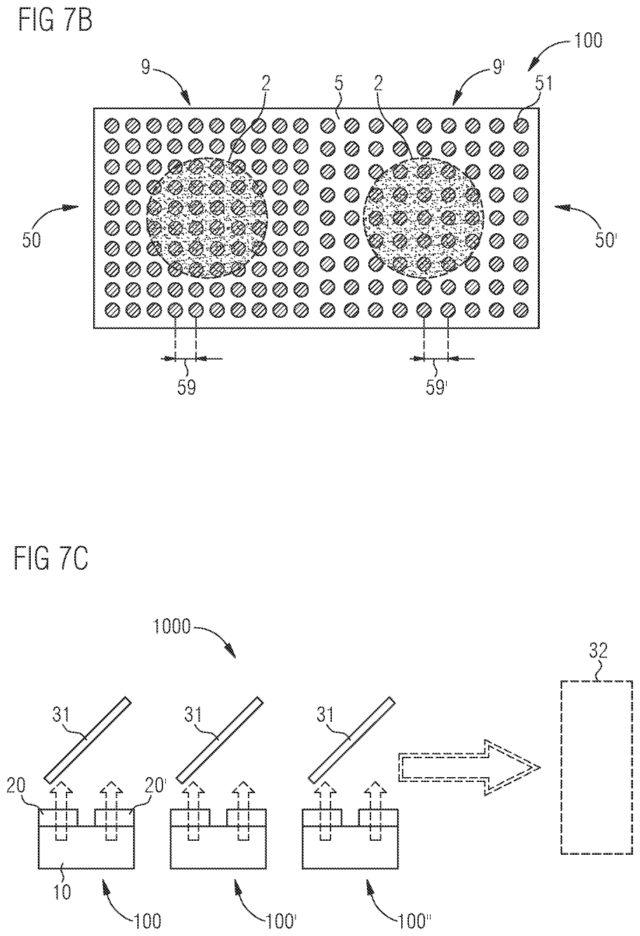

FIGS. 7A, 7B and 7C show semiconductor laser devices 100 and a projection device 1000 with such semiconductor laser devices.

FIG. 7A shows a schematic illustration of a photonic crystal semiconductor laser device 100 that has two separated electrical contact layers 2, resulting in two emission regions 9, 9′. Thus, the photonic crystal semiconductor laser device can have the first emission region 9 and the second emission region 9′ arranged next to each other in a lateral direction, wherein each of the emission regions 9, 9′ can be operated to emit light via the light-outcoupling surface. For example, the at least two emission regions 9, 9′ can be operated independently from each other. Alternatively, the at least two emission regions 9, 9′ can be operated simultaneously.

In FIG. 7B, a semiconductor laser device 100 is shown that has a first photonic crystal structure 50 in the first emission region 9 and a second photonic crystal structure 50′ in the second emission region 9′, wherein the first and the second photonic crystal structures 50, 50′ are different. In particular, the first photonic crystal structure 50 can comprise a two-dimensional lattice-like first matrix of discontinuities 51 in the photonic crystal layer 5 and the second photonic crystal structure 50′ can comprise a two-dimensional lattice-like second matrix of discontinuities 51 in the photonic crystal layer 5, wherein the first and the second two-dimensional matrices differ regarding one or more parameters chosen from a lattice constant 59, 59′, a density of discontinuities 51, a mean size of the discontinuities 51, a material of the discontinuities. The mean size of the discontinuities 51 of each of the photonic crystal structures 50, 50′ can be, for instance, an average diameter or an average area, measured in a plane parallel to the main extension plane of the active layer, of the discontinuities 51 of the respective photonic crystal structure 50, 50′. In the embodiment shown in FIG. 7B, the first and second photonic crystal structures 50, 50′ differ, by way of example, with regard to the lattice constants 59, 59′.

Since the wavelength of the light produced in the active layer and amplified in the semiconductor laser device 100 depends on the properties of the photonic crystal structure in an active region, the photonic crystal semiconductor laser device 100 shown in FIG. 7B can produce and emit light with a first wavelength from the first emission region 9 and light with a second wavelength different from the first wavelength from the second emission region 9′. Due to the more than one photonic crystal structures 50, 50′ in the photonic crystal layer 5, the photonic crystal semiconductor laser device 100 can thus be configured as a multi-wavelength emitter emitting at least two light beams with different wavelengths. In particular, the second wavelength can be slightly detuned with respect to the first wavelength.

For example, the first emission region can emit light with a central wavelength λ, while the second emission region can emit light with a central wavelength λ+Δλ. Both the light emitted by the first emission region and the light emitted by the second emission region can have a respective spectral width with, for example, an FWHM of several nm, for instance less than 10 nm or less than 5 nm. For example, Δλ can be equal to or greater than the FWHM. This can also mean that Δλ is equal to or greater than 2 nm and less than or equal to 10 nm or less than or equal to 5 nm.

By overlapping the light beams emitted by the first and second emission region 9, 9′, the wavelength detuning causes a reduction of interference effects like speckle patterns that could be perceived by an observer. To a human observer, the light beams emitted by the different emission regions 9, 9′ can appear to have the same color, so that the photonic crystal semiconductor laser device 100 emits, for a human observer, just several light beams with the same color.

For instance, for both semiconductor laser devices 100 shown in FIGS. 7A and 7B, respectively, a common integrated optical element can be placed over both emission regions 9, 9′.

As indicated in the projection device 100 shown in FIG. 7C, however, it can also be possible that a first integrated optical element 20 can be arranged on the first emission region and a second integrated optical element 20′ can be arranged on the second emission region. The first and second integrated optical elements 20, 20′ can be embodied as described before and can be similar or different to each other.

It can for example be possible that the first and second emission region are embodied similarly as explained in connection with FIG. 7A, while the first and second integrated optical element 20, 20′ are embodied as different wavelength filters. For instance, the first and second integrated optical element 20, 20′ can be embodied as VBGs having different properties so that the first emission region is forced to emit light with a first wavelength and the second emission region is forced to emit light with a second wavelength that is different from the first wavelength.

For instance, if the wavelength drift over temperature of the semiconductor laser device 100 is too high, one can use, alternatively or in addition to using an active temperature control, a semiconductor laser device 100 with more than one emission region, emitting light with slightly different wavelengths, and can switch, depending on the temperature, between the different emission regions. The emission regions are next to each other, on the same chip, but are slightly detuned in wavelength either by having different integrated optical elements 20, 20′ with different VBG conditions or by having emission regions 9, 9′ with different photonic crystal structures 50, 50′, as explained in connection with FIG. 7B, or both. As there is no additional optics involved, a semiconductor laser device with more than one emission region requires only some more chip space, which is not too expensive in regard to volume and housing.

Furthermore, when utilizing a semiconductor laser device having more than one emission region in a projection device as a laser beam scanning module, multiple emission regions increase the resolution and help to overcome flicker, particularly for HUD applications which require larger mirrors to accommodate a larger scanning image. Multiple emission regions can also help to overcome problems with a lower than 120 Hz scanning speed.

Alternatively or additionally to the features described in connection with the figures, the embodiments shown in the figures can comprise further features described in the general part of the description. Moreover, features and embodiments of the figures can be combined with each other, even if such combination is not explicitly described.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

### REFERENCE NUMERALS

1 active layer
2, 2′ electrical contact layer
3 first cladding layer
4 second cladding layer
5 photonic crystal layer
9, 9′ emission region
10 semiconductor layer sequence
11 light-outcoupling surface
12 substrate
13 rear surface
14 buffer layer
15 semiconductor contact layer
20 integrated optical element
21 grating structure
22 material
23, 23′ polarizer
24 material
25 input surface
26 output surface
27 spacer element
28 gap
29 plate element
31 beam combining element
32 scanning mirror
50, 50′ photonic crystal structure
51 discontinuity
59, 59′ lattice constant
99 light
100, 100′, 100″ semiconductor laser device
101, 102 method step
1000 projection device

1. A semiconductor laser device comprising:
an active layer having a main extension plane;
a first cladding layer and a second cladding layer, the active layer being arranged between the first and second cladding layer in a direction perpendicular to the main extension plane;
a light-outcoupling surface parallel to the main extension direction and arranged on a side of the second cladding layer opposite to the active layer;
a photonic crystal layer arranged in the first cladding layer or in the second cladding layer; and
an integrated optical element directly fixed to the light-outcoupling surface.

2. The semiconductor laser device according to claim 1, wherein the integrated optical element comprises a wavelength filter.

3. The semiconductor laser device according to claim 1, wherein the integrated optical element comprises a volume Bragg grating.

4. The semiconductor laser device according to claim 1, wherein the integrated optical element comprises an optical isolator.

5. The semiconductor laser device according to claim 1, wherein the integrated optical element comprises a polarization converter.

6. The semiconductor laser device according to claim 1, wherein the integrated optical element comprises a plate element with an input surface facing the light-outcoupling surface and an output surface facing away from the light-outcoupling surface.

7. The semiconductor laser device according to claim 6, wherein the input surface is directly mounted onto the light-outcoupling surface.

8. The semiconductor laser device according to claim 6, wherein the integrated optical element comprises a spacer element on the input surface of the plate element, the spacer element being directly mounted onto the light-outcoupling surface.

9. The semiconductor laser device according to claim 8, wherein the spacer element has a plate-like form or a frame-like form.

10. The semiconductor laser device according to claim 8, wherein the spacer element comprises glass.

11. The semiconductor laser device according to claim 1, wherein the semiconductor laser device comprises at least one first emission region and at least one second emission region arranged next to each other in a direction parallel to the main extension plane.

12. The semiconductor laser device according to claim 11, wherein the integrated optical element is arranged on both the at least one first emission region and the at least one second emission region.

13. The semiconductor laser device according to claim 11, wherein a first integrated optical element is arranged on the at least one first emission region and a second integrated optical element is arranged on the at least one second emission region.

14. The semiconductor laser device according to claim 13, wherein the first integrated optical element and the second integrated optical element comprise different wavelength filters.

15. The semiconductor laser device according to claim 11, wherein the photonic crystal layer comprises a first photonic crystal structure in the first emission region and a second photonic crystal structure in the second emission region, wherein the first and the second photonic crystal structures are different.

16. A method for manufacturing a semiconductor laser device,
wherein a semiconductor layer sequence is provided, the semiconductor layer sequence comprising
an active layer having a main extension plane,
a first cladding layer and a second cladding layer, the active layer being arranged between the first and second cladding layer in a direction perpendicular to the main extension plane,
a light-outcoupling surface parallel to the main extension direction and arranged on a side of the second cladding layer opposite to the active layer, and
a photonic crystal layer arranged in the first cladding layer or in the second cladding layer,
wherein an integrated optical element is directly fixed to the light-outcoupling surface, and
wherein at least a part of the integrated optical element is manufactured on the light-outcoupling surface.

17. A projection device comprising a plurality of semiconductor laser devices according to claim 1.
